(19) United States
(12) Patent Application Publication
(10) Pub. No.: US 2026/0123197 A1
(43) Pub. Date: Apr. 30, 2026

(54) Display Device

(71) Applicant: LG Display Co., Ltd., Seoul (KR)

(72) Inventors: Wonyeol Choi, Paju-si (KR); Seonhee Lee, Paju-si (KR); Kang Sukhyun, Paju-si (KR)

(21) Appl. No.: 19/193,152

(22) Filed: Apr. 29, 2025

(30) Foreign Application Priority Data
Oct. 31, 2024 (KR) 10-2024-0151832

(51) Int. Cl. H10K 59/124; H10K 59/122; H10K 59/80

(52) U.S. Cl. CPC H10K 59/124; H10K 59/122; H10K 59/873

(57) ABSTRACT

A display device is disclosed that is capable of preventing or at least reducing moisture penetration by including a substrate, a first planarization layer disposed on the substrate, a second planarization layer positioned on the first planarization layer, a bank pattern disposed on the second planarization layer, and a spacer, wherein the third encapsulation layer and the first encapsulation layer corresponding to the first protrusion, the second protrusion, the third protrusion, and the fourth protrusion contact each other, and the second encapsulation layer is disposed between the first protrusion, the second protrusion, the third protrusion, and the fourth protrusion, and the third encapsulation layer.

### CROSS-REFERENCE TO RELATED APPLICATION

This application claims priority from Republic of Korea Patent Application No. 10-2024-0151832 filed on Oct. 31, 2024, which is hereby incorporated by reference in its entirety.

### BACKGROUND

### Field

Embodiments of the disclosure relate to a display device and a display panel and, more specifically, to a display device and a display panel capable of enhancing the sealing function of a light emitting element.

### Description of Related Art

The organic light emitting display device may include organic light emitting diodes respectively arranged in a plurality of subpixels disposed on a display panel and cause each subpixel to emit light by controlling the driving current flowing to the organic light emitting diode through a driving transistor to display images.

In this case, an encapsulation layer may be disposed at the upper portion of the display panel to prevent external moisture or oxygen from penetrating into the light emitting element.

However, as display panels slim down, a need arises for a technology that reduces the thickness of the bezel and eliminates the dam.

### SUMMARY

Embodiments of the disclosure may provide a display device in which the flow of an encapsulation layer is controlled.

Embodiments of the disclosure may provide a display device with a reduced bezel thickness.

A display device according to embodiments of the disclosure may comprise a substrate, a planarization layer disposed on the substrate, a first electrode disposed on the planarization layer, a bank pattern disposed on the first electrode, a second electrode disposed on the bank pattern, a first encapsulation layer disposed on the second electrode, a second encapsulation layer disposed on the first encapsulation layer, and a third encapsulation layer disposed on the second encapsulation layer. The third encapsulation layer may be disposed to contact the first encapsulation layer at a portion corresponding to the first to third protrusions.

In the display device according to embodiments of the disclosure, the first encapsulation layer may include a step, and the step may have a step shape.

In the display device according to embodiments of the disclosure, the second encapsulation layer may be disposed between at least a portion of the first to third stepped portions and the third encapsulation layer.

According to embodiments of the disclosure, there may be provided a display device in which the flow of an encapsulation layer is easily controlled by disposing a spacer and a multi-layered organic film.

According to embodiments of the disclosure, there may be provided a display device in which the flow of an encapsulation layer is easily controlled by adjusting the angle of a multi-layered organic film.

Embodiments of the disclosure may provide a display device capable of securing a moisture proofing capacity by forming an encapsulation layer on the upper surface and side surface of a multi-layered organic film to prevent or at least reduce exposure of the encapsulation layer to the outside.

### BRIEF DESCRIPTION OF DRAWINGS

The above and other objects, features, and advantages of the disclosure will be more clearly understood from the following detailed description, taken in conjunction with the accompanying drawings, in which:

FIG. 1 is a view illustrating a system configuration of a display device according to embodiments of the disclosure;

FIG. 2 illustrates a display panel according to an embodiment of the disclosure;

FIG. 3 is a cross-sectional view illustrating a display panel according to embodiments of the disclosure;

FIG. 4 is a cross-sectional view of a display panel according to an embodiment of the disclosure;

FIGS. 5 to 8 are cross-sectional views illustrating a process of forming the display panel of FIG. 4 according to an embodiment of the disclosure;

FIG. 9 is a plan view according to the display panel of FIG. 4 according to an embodiment of the disclosure;

FIG. 10 is a cross-sectional view of a display panel according to another embodiment of the disclosure; and

FIG. 11 is a plan view of the display panel of FIG. 10 according to an embodiment of the disclosure.

### DETAILED DESCRIPTION

In the following description of examples or embodiments of the disclosure, reference will be made to the accompanying drawings in which it is shown by way of illustration specific examples or embodiments that can be implemented, and in which the same reference numerals and signs can be used to designate the same or like components even when they are shown in different accompanying drawings from one another. Further, in the following description of examples or embodiments of the disclosure, detailed descriptions of well-known functions and components incorporated herein will be omitted when it is determined that the description may make the subject matter in some embodiments of the disclosure rather unclear. The terms such as “including”, “having”, “containing”, “constituting” “make up of”, and “formed of” used herein are generally intended to allow other components to be added unless the terms are used with the term “only”. As used herein, singular forms are intended to include plural forms unless the context clearly indicates otherwise.

Terms, such as “first”, “second”, “A”, “B”, “(A)”, or “(B)” may be used herein to describe elements of the disclosure. Each of these terms is not used to define essence, order, sequence, or number of elements etc., but is used merely to distinguish the corresponding element from other elements.

When it is mentioned that a first element “is connected or coupled to”, “contacts or overlaps” etc. a second element, it should be interpreted that, not only can the first element “be directly connected or coupled to” or “directly contact or overlap” the second element, but a third element can also be “interposed” between the first and second elements, or the first and second elements can “be connected or coupled to”, “contact or overlap”, etc. each other via a fourth element. Here, the second element may be included in at least one of two or more elements that “are connected or coupled to”, “contact or overlap”, etc. each other.

When time relative terms, such as “after,” “subsequent to,” “next,” “before,” and the like, are used to describe processes or operations of elements or configurations, or flows or steps in operating, processing, manufacturing methods, these terms may be used to describe non-consecutive or non-sequential processes or operations unless the term “directly” or “immediately” is used together.

In addition, when any dimensions, relative sizes etc. are mentioned, it should be considered that numerical values for an elements or features, or corresponding information (e.g., level, range, etc.) include a tolerance or error range that may be caused by various factors (e.g., process factors, internal or external impact, noise, etc.) even when a relevant description is not specified. Further, the term “may”fully encompasses all the meanings of the term “can”.

Hereinafter, various embodiments of the disclosure are described in detail with reference to the accompanying drawings.

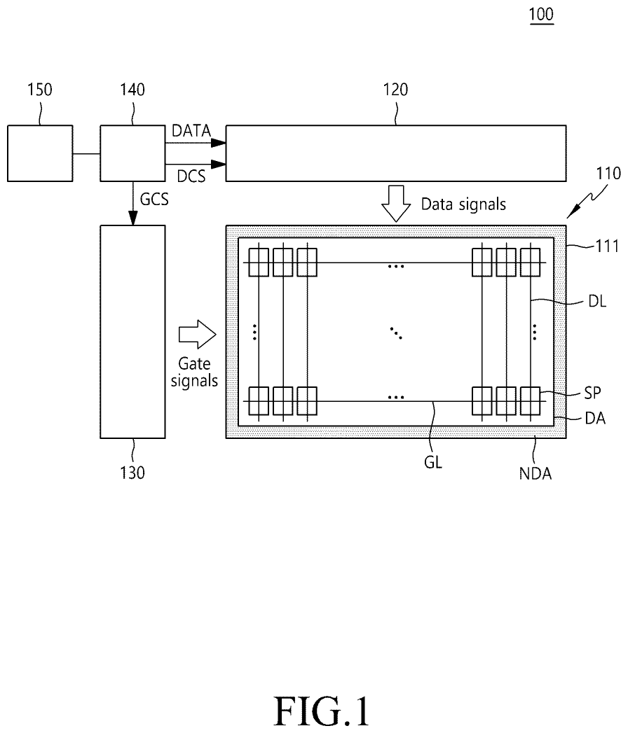

FIG. 1 is a view illustrating a system configuration of a display device 100 according to embodiments of the disclosure.

Referring to FIG. 1, a display device 100 according to embodiments of the disclosure may include a display panel 110 and display driving circuits, as components for displaying images. The display driving circuits are circuits for driving the display panel 110 and may include a data driving circuit 120, a gate driving circuit 130, and a controller 140.

The display panel 110 may include a substrate 111 and a plurality of subpixels SP disposed on the substrate 111.

The substrate 111 may include a display area DA capable of displaying an image and a non-display area NDA positioned outside the display area DA.

The display area DA may also be referred to as an active area, and a plurality of subpixels SP for displaying an image may be disposed in the display area DA. The non-display area NDA may also be referred to as a non-active area and may include a pad area.

In the display panel 110 according to embodiments of the disclosure, the non-display area NDA may be very small. In the disclosure, the non-display area NDA is also referred to as a “bezel.” For example, the non-display area NDA may include a first non-display area positioned outside in the first direction from the display area DA, a second non-display area positioned outside in the second direction from the display area DA, a third non-display area positioned outside in a direction opposite to the first direction from the display area DA, and a fourth non-display area positioned outside in a direction opposite to the second direction from the display area DA.

The first non-display area may include a pad area to which a driving circuit is connected or bonded. The second to fourth non-display areas may have a very small size.

As another example, the boundary area between the display area DA and the non-display area NDA may be bent so that the non-display area NDA may be positioned under the display area. In this case, no or little change may be made to the non-display area NDA shown to the user when the user views the display area 100 from the front. For example, the first non-display area may include a bending area. As the bending area is bent, the first non-display area may not be visible from the front.

Various types of signal lines for driving a plurality of subpixels SP may be disposed on the substrate 111 of the display panel 110.

The display device 100 according to embodiments of the disclosure may be a liquid crystal display device or a self-emission display device in which the display panel 110 emits light by itself. When the display device 100 according to the embodiments of the disclosure is a self-emission display device, each of the plurality of subpixels SP may include a light emitting element.

For example, the display device 100 according to embodiments of the disclosure may be an organic light emitting diode display in which the light emitting element is implemented as an organic light emitting diode (OLED). As another example, the display device 100 according to embodiments of the disclosure may be an inorganic light emitting display device in which the light emitting element is implemented as an inorganic material-based light emitting diode. As another example, the display device 100 according to embodiments of the disclosure may be a quantum dot display device in which the light emitting element is implemented as a quantum dot which is self-emission semiconductor crystal.

The structure of each of the plurality of subpixels SP may vary according to the type of the display device 100. For example, when the display device 100 is a self-emission display device in which the subpixels SP emit light by themselves, each subpixel SP may include a light emitting element that emits light by itself, one or more transistors, and one or more capacitors.

For example, various types of signal lines may include a plurality of data lines DL transferring data signals (also referred to as data voltages or image signals) and a plurality of gate lines GL transferring gate signals (also referred to as scan signals).

The plurality of data lines DL and the plurality of gate lines GL may cross each other. Each of the plurality of data lines DL may be disposed to extend in the first direction. Each of the plurality of gate lines GL may be disposed to extend in the second direction. The first direction may be a column direction, and the second direction may be a row direction. The first direction may be the row direction, and the second direction may be the column direction. For convenience of description, in the following examples, the first direction is the column direction, and the second direction is the row direction. Thus, described below is an example in which each of the plurality of data lines DL is disposed in the column direction, and each of the plurality of gate lines GL is disposed in the row direction, but embodiments of the disclosure are not limited thereto.

The data driving circuit 120 is a circuit for driving the plurality of data lines DL and may out data signals to the plurality of data lines DL.

The data driving circuit 120 may receive digital image data DATA from the controller 140 and may convert the received image data DATA into analog data signals and output them to the plurality of data lines DL.

For example, the data driving circuit 120 may be connected with the display panel 110 by a tape automated bonding (TAB) method or connected to a bonding pad of the display panel 110 by a chip on glass (COG) or chip on panel (COP) method or may be implemented by a chip on film (COF) method and connected with the display panel 110, but embodiments of the disclosure are not limited thereto.

The data driving circuit 120 may be connected to one side (e.g., an upper or lower side) of the display panel 110. In contrast, depending on the driving scheme or the panel design scheme, data driving circuits 120 may be connected with both the sides (e.g., both the upper and lower sides) of the display panel 110, or two or more of the four sides of the display panel 110.

The data driving circuit 120 may be connected outside the display area DA of the display panel 110, but as another example, the data driving circuit 120 may be disposed in the display area DA of the display panel 110.

The gate driving circuit 130 is a circuit for driving the plurality of gate lines GL, and may output gate signals to the plurality of gate lines GL.

The gate driving circuit 130 may receive a first gate voltage corresponding to a turn-on level voltage and a second gate voltage corresponding to a turn-off level voltage, along with various gate driving control signals GCS, generate gate signals, and supply the generated gate signals to the plurality of gate lines GL.

In the display device 100 according to embodiments of the disclosure, the gate driving circuit 130 may be embedded, in a gate in panel (GIP) type, in the display panel 110. When the gate driving circuit 130 is of the gate in panel type, the gate driving circuit 130 may be formed on the substrate 111 of the display panel 110 during the manufacturing process of the display panel 110.

For example, the gate driving circuit 130 may be disposed in the non-active area NDA of the display panel 110.

As another example, the gate driving circuit 130 may be disposed in the display area DA of the display panel 110. In this case, for example, the gate driving circuit 130 may be disposed in a first partial area in the display area DA (e.g., a left area or a right area in the display area DA). As another example, the gate driving circuit 130 may be disposed in a first partial area in the display area DA (e.g., a left area or right area in the display area DA) and a second partial area (e.g., a right area or left area in the display area DA).

In the disclosure, the gate driving circuit 130 embedded in the display panel 110 in a gate-in-panel type may also be referred to as a “gate-in-panel circuit.”

The controller 140 is a device for controlling the data driving circuit 120 and the gate driving circuit 130 and may control driving timings for the plurality of data lines DL and driving timings for the plurality of gate lines GL.

The controller 140 may supply a data driving control signal DCS to the data driving circuit 120 to control the data driving circuit 120 and may supply a gate driving control signal GCS to the gate driving circuit 130 to control the gate driving circuit 130.

The controller 140 may receive input image data from the host system 150 and supply image data DATA to the data driving circuit 120 based on the input image data.

The controller 140 may be implemented as a separate component from the data driving circuit 120, or the controller 140 and the data driving circuit 120 may be integrated into an integrated circuit (IC).

The controller 140 may be a timing controller used in display technology, a control device that may perform other control functions as well as the functions of the timing controller, or a control device other than the timing controller, or may be a circuit in the control device. The controller 140 may be implemented as various circuits or electronic components, such as an integrated circuit (IC), a field programmable gate array (FPGA), an application specific integrated circuit (ASIC), or a processor, but is not limited thereto.

The controller 140 may be mounted on a printed circuit board or a flexible printed circuit and may be electrically connected with the data driving circuit 120 and the gate driving circuit 130 through the printed circuit board or the flexible printed circuit.

The controller 140 may transmit/receive signals to/from the data driving circuit 120 according to one or more predetermined interfaces. The interface may include, e.g., a low voltage differential signaling (LVDS) interface, an embedded clock point-point interface (EPI) interface, and a serial peripheral interface (SPI), but embodiments of the disclosure are not limited thereto.

To provide a touch sensing function as well as an image display function, the display device 100 according to embodiments of the disclosure may include a touch sensor and a touch sensing circuit that senses the touch sensor to detect whether a touch occurs by a touch object, such as a finger or pen, or the position of the touch.

The touch sensing circuit may include a touch driving circuit that drives and senses the touch sensor and generates and outputs touch sensing data and a touch controller that may detect an occurrence of a touch or the position of the touch using touch sensing data.

The touch sensor may include a plurality of touch electrodes. The touch sensor may further include a plurality of touch lines for electrically connecting the plurality of touch electrodes and the touch driving circuit.

The touch sensor may be present in a touch panel form outside the display panel 110 or may be present inside the display panel 110. When the touch panel, in the form of a touch panel, exists outside the display panel 110, the touch panel is referred to as an external type. When the touch sensor is of the external type, the touch panel and the display panel 110 may be separately manufactured or may be combined during an assembly process. The external-type touch panel may include a touch panel substrate and a plurality of touch electrodes on the touch panel substrate.

When the touch sensor is present inside the display panel 110, the touch sensor may be formed on the substrate, together with signal lines and electrodes related to display driving, during the manufacturing process of the display panel 110.

The touch driving circuit may supply a touch driving signal to at least one of the plurality of touch electrodes and may sense at least one of the plurality of touch electrodes to generate touch sensing data.

The touch sensing circuit may perform touch sensing in a self-capacitance sensing scheme or a mutual-capacitance sensing scheme.

When the touch sensing circuit performs touch sensing in the self-capacitance sensing scheme, the touch sensing circuit may perform touch sensing based on capacitance between each touch electrode and the touch object (e.g., finger or pen). According to the self-capacitance sensing scheme, each of the plurality of touch electrodes may serve both as a driving touch electrode and as a sensing touch electrode. The touch driving circuit may drive all or some of the plurality of touch electrodes and sense all or some of the plurality of touch electrodes.

When the touch sensing circuit performs touch sensing in the mutual-capacitance sensing scheme, the touch sensing circuit may perform touch sensing based on capacitance between the touch electrodes. According to the mutual-capacitance sensing scheme, the plurality of touch electrodes are divided into driving touch electrodes and sensing touch electrodes. The touch driving circuit may drive the driving touch electrodes and sense the sensing touch electrodes.

The touch driving circuit and the touch controller included in the touch sensing circuit may be implemented as separate devices or as a single device. The touch driving circuit and the data driving circuit may be implemented as separate devices or as a single device.

The display device 100 may further include a power supply circuit for supplying various types of power to the display driver integrated circuit and/or the touch sensing circuit.

The display device 100 according to embodiments of the disclosure may be a mobile terminal, such as a smart phone or a tablet, or a monitor or television (TV) in various sizes but, without limited thereto, may be a display in various types and various sizes capable of displaying information or images.

The display device 100 according to embodiments of the disclosure may further include an electronic device such as a camera (image sensor), a detection sensor, or the like. For example, the detection sensor may be a sensor that detects an object or a human body by receiving light such as infrared rays, ultrasonic waves, or ultraviolet rays.

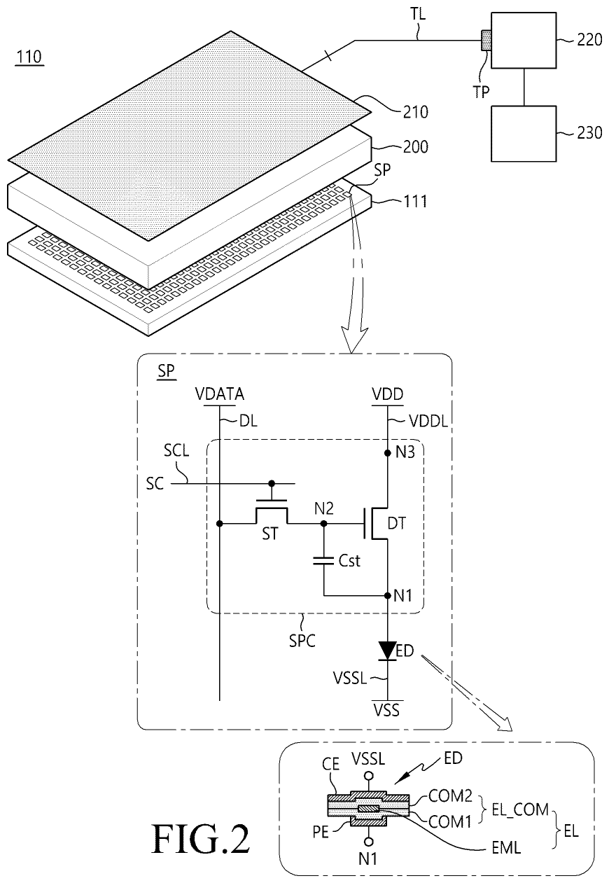

FIG. 2 illustrates a display panel 110 according to an embodiment of the disclosure. Features that identical or similar to those described with reference to FIG. 1 are omitted from the following description or briefly described below.

Referring to FIG. 2, the display panel 110 may include a substrate 111 disposed in a plurality of subpixels SP and an encapsulation layer 200 on the substrate 111. The encapsulation layer 200 may also be referred to as an encapsulation substrate or an encapsulation unit.

Referring to FIG. 2, when the display device 100 according to embodiments of the disclosure is a self-luminous display device, each of the plurality of subpixels SP disposed on the substrate 111 may include a light emitting element ED and a subpixel circuit SPC for driving the light emitting element ED.

Referring to FIG. 2, the subpixel circuit SPC may include a plurality of transistors for driving the light emitting element ED and at least one capacitor. In the disclosure, the subpixel circuit SPC may drive the light emitting element ED by supplying a driving current to the light emitting element ED at a predetermined timing. The light emitting element ED may be driven by a driving current to emit light.

The plurality of transistors may include a driving transistor DT for driving the light emitting element ED and a scan transistor ST that is turned on or off according to the scan signal SC.

The driving transistor DT may supply a driving current to the light emitting element ED.

The scan transistor ST may be configured to control the electrical state of a corresponding node in the subpixel circuit SPC or to control the state or operation of the driving transistor DT.

The at least one capacitor may include a storage capacitor Cst for maintaining a constant voltage during a frame.

To drive the subpixel SP, a data signal VDATA as an image signal and a scan signal SC as a gate signal may be applied to the subpixel SP. Further, for driving the subpixel SP, a common driving voltage including the first common driving voltage VDD and the second common driving voltage VSS may be applied to the subpixel SP.

The light emitting element ED may include a pixel electrode PE, an intermediate layer EL, and a common electrode CE. The intermediate layer EL may be disposed between the pixel electrode PE and the common electrode CE.

For example, the pixel electrode PE may be an electrode disposed in each subpixel SP, and the common electrode CE may be an electrode commonly disposed in all the subpixels SP. For example, the pixel electrode PE may be an anode, and the common electrode CE may be a cathode. As another example, the pixel electrode PE may be a cathode, and the common electrode CE may be an anode. For convenience of description, an example is described in which the pixel electrode PE is an anode, and the common electrode CE is a cathode.

When the light emitting element ED is an organic light emitting element, the intermediate layer EL may include a light emitting layer EML, a first common intermediate layer COM1 between the pixel electrode PE and the light emitting layer EML, and a second common intermediate layer COM2 between the light emitting layer EML and the common electrode CE. The first common intermediate layer COM1 and the second common intermediate layer COM2 may be collectively referred to as a common intermediate layer EL_COM.

The light emitting layer EML may be disposed for each subpixel SP. The common intermediate layer EL_COM may be disposed commonly across a plurality of subpixel SP.

The light emitting layer EML may be disposed for each light emitting area, and the common intermediate layer EL_COM may be commonly disposed over the plurality of light emitting areas and the non-light emitting area.

For example, the first common intermediate layer COM1 may include a hole injection layer HIL and a hole transport layer HTL. The second common intermediate layer COM2 may include an electron transport layer ETL and an electron injection layer EIL.

The hole injection layer may inject holes from the pixel electrode PE to the hole transport layer, and the hole transport layer may transport holes to the light emitting layer EML. The electron injection layer may inject electrons from the common electrode CE to the electron transport layer, and the electron transport layer may transport electrons to the light emitting layer EML.

For example, the common electrode CE may be electrically connected to the second common driving voltage line VSSL. The second common driving voltage VSS may be applied to the common electrode CE through the second common driving voltage line VSSL. The pixel electrode PE may be electrically connected directly or indirectly (through another transistor) to the first node N1 of the driving transistor DT of each subpixel SP. In the disclosure, “the second common driving voltage VSS” may also be referred to as a “base voltage”, and “the second common driving voltage line VSSL” may also be referred to as a “low-potential power voltage line” or “base voltage line”.

Each light emitting element ED may include portions where the pixel electrode PE, the light emitting layer EML in the intermediate layer LE, and the common electrode CE overlap. A predetermined light emitting area may be formed by each light emitting element ED. For example, the light emitting area of each light emitting element ED may include an overlapping area of the pixel electrode PE, the light emitting layer EML in the intermediate layer EL, and the common electrode CE.

For example, the light emitting element ED may be an organic light emitting diode (OLED), an inorganic light emitting diode (LED), or a quantum dot light emitting element. For example, when the light emitting element ED is an organic light emitting diode (OLED), the intermediate layer EL of the light emitting element ED may include an intermediate layer EL including an organic material.

The driving transistor DT may be a driving transistor for supplying a driving current to the light emitting element ED. The driving transistor DT may be connected between the first common driving voltage line VDDL and the light emitting element ED.

The driving transistor DT may include a first node N1, a second node N2, and a third node N3. The first node N1 may be electrically connected to the light emitting element ED. A data signal VDATA may be applied to the second node N2. A first common driving voltage VDD may be applied to the third node N3 from the first common driving voltage line VDDL.

In the driving transistor DT, the second node N2 may be a gate node, the first node N1 may be a source node or a drain node, and the third node N3 may be a drain node or a source node. Hereinafter, for convenience of description, an example is described in which in the driving transistor DT, the second node N2 may be a gate node (or gate electrode), the first node N1 may be a source node (or source electrode), and the third node N3 may be a drain node (or drain electrode), but embodiments of the disclosure are not limited thereto.

The scan transistor ST included in the subpixel circuit SPC illustrated in FIG. 2 may be a switching transistor for transferring the data signal VDATA, which is an image signal, to the second node N2, which is the gate node of the driving transistor DT.

The scan transistor ST may be controlled to be turned on and off by the scan signal SC, which is a gate signal applied through the scan line SCL, which is a type of the gate line GL, to control electrical connection between the second node N2 of the driving transistor DT and the data line DL. The drain electrode or source electrode of the scan transistor ST may be electrically connected to the data line DL. The source electrode or drain electrode of the scan transistor ST may be electrically connected to the second node N2 of the driving transistor DT. The gate electrode of the scan transistor ST may be electrically connected to the scan line SCL.

The storage capacitor Cst may be electrically connected between the first node N1 and second node N2 of the driving transistor DT. The storage capacitor Cst may include a first capacitor electrode electrically connected to the first node N1 of the driving transistor DT or corresponding to the first node N1 of the driving transistor DT, and a second capacitor electrode electrically connected to the second node N2 of the driving transistor DT or corresponding to the second node N2 of the driving transistor DT.

The capacitor Cst may be an external capacitor designed to be outside the driving transistor DT, but not a parasite capacitor (e.g., Cgs or Cgd) which is an internal capacitor that may be present between the first node N1 and the second node N2 of the driving transistor DT.

Each of the driving transistor DT and the scan transistor ST may be an n-type transistor or a p-type transistor.

The display panel 110 may have a top emission structure or a bottom emission structure.

When the display panel 110 has a top emission structure, at least a portion of the subpixel circuit SPC may overlap at least a portion of the light emitting element ED in a vertical direction. Accordingly, the area of the emission area may increase and the aperture ratio may increase.

When the display panel 110 has a bottom emission structure, the subpixel circuit SPC may not overlap the light emitting element ED in the vertical direction.

As illustrated in FIG. 2, the subpixel circuit SPC may have a 2T (transistor)1C (capacitor) structure including two transistors DT and ST and one capacitor Cst. In some cases, the subpixel circuit SPC may further include one or more transistors or may further include one or more capacitors.

For example, the subpixel circuit SPC may have an 8T1C structure including 8 transistors and 1 capacitor. As another example, the subpixel circuit SPC may have a 6T2C structure including 6 transistors and 2 capacitors. As another example, the subpixel circuit SPC may have a 7T1C structure including 7 transistors and 1 capacitor. Embodiments of the disclosure are not limited thereto.

Depending on the structure of the subpixel circuit SPC, the type and number of gate lines or the gate signals supplied to the subpixel SP may vary. Further, the type and the number of common driving voltages supplied to the subpixel SP may vary depending on the structure of the subpixel circuit SPC.

Referring to FIG. 2, since the circuit elements (e.g., the light emitting element ED implemented as an organic light emitting diode (OLED) including an organic material) in each subpixel SP are vulnerable to external moisture or oxygen, the encapsulation layer 200 for preventing or at least reducing external moisture or oxygen from penetrating into the circuit elements (e.g., the light emitting element ED) may be disposed on the display panel 110.

The encapsulation layer 200 may be configured in various forms so that the light emitting elements ED do not contact moisture or oxygen. For example, the encapsulation layer 200 may be constituted of two or more layers in which organic layers and inorganic layers are alternately stacked, but embodiments of the disclosure are not limited thereto.

Referring to FIG. 2, a display device 100 according to embodiments of the disclosure may include a touch sensor layer 210 including a plurality of sensor electrodes to sense the user's touch, a touch driving circuit 220 configured to sense the plurality of sensor electrodes, and a touch controller 230 configured to determine the presence or absence of a touch or touch coordinates using the sensing result (touch sensing data) of the touch driving circuit 220.

The touch sensor layer 210 may be embedded in the display panel 110. For example, the touch sensor layer 210 may be disposed on the encapsulation layer 200 in the display panel 110.

The display panel 110 may further include a plurality of touch pads TP electrically connected to the touch driving circuit 220 and a plurality of touch lines TL for electrically connecting the plurality of sensor electrodes included in the touch sensor layer 210 to the plurality of touch pads TP connected to the touch driving circuit 220.

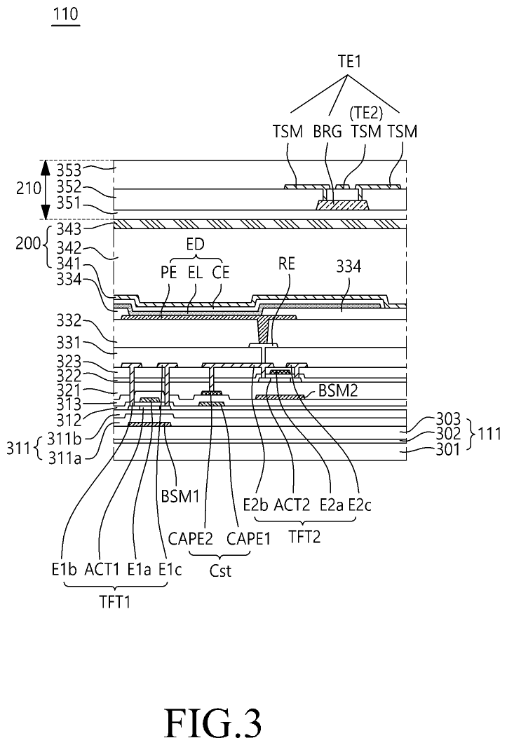

FIG. 3 is a cross-sectional view of a display panel 110 according to embodiments of the disclosure. What is identical or similar to those described in connection with FIGS. 1 and 2 may be omitted or briefly described below.

Referring to FIG. 3, the display panel 110 according to embodiments of the disclosure may include a transistor forming unit, a light emitting element forming unit, and an encapsulation unit from a vertical structure perspective.

The substrate 111 may be a single layer or multiple layers. The substrate 111 may be formed of glass or a plastic material. When the substrate 111 includes multiple layers, the substrate 111 may include a first substrate 301, a substrate intermediate layer 302, and a second substrate 303. The substrate intermediate layer 302 may be positioned between the first substrate 301 and the second substrate 303. For example, each of the first substrate 301 and the second substrate 303 may be a polyimide (PI) layer. The substrate intermediate layer 302 may be an inorganic insulation layer. When an electric charge is charged to the first substrate 301 which is a polyimide layer, the substrate intermediate layer 302 may prevent or at least reduce the electric charge from affecting transistors disposed on the second substrate 303 through the second substrate 303 which is a polyimide layer.

Further, the substrate intermediate layer 302 may prevent or at least reduce a moisture component from penetrating upward through the first substrate 301. For example, the substrate intermediate layer 302 may be formed of a single layer of silicon nitride (SiNx) or silicon oxide (SiOx) or multiple layers thereof, or may be formed of a double layer of silicon dioxide (SiOx) and silicon nitride (SiNx), but is not limited thereto.

The transistor forming unit may include a substrate 111, various insulation layers 311, 312, 313, 321, 322, and 323 on the substrate 111, various transistors TFT1 and TFT2, a storage capacitor Cst, and various electrodes or signal lines.

The transistors TFT1 and TFT2 included in the transistor forming unit may include a first transistor TFT1 and a second transistor TFT2.

The first transistor TFT1 may include a first active layer ACT1, a first electrode E1a, a second electrode E1b, and a third electrode E1c. The first active layer ACT1 may be a first semiconductor layer, but embodiments of the disclosure are not limited thereto. For example, the first active layer ACT1 may be formed of an oxide semiconductor, amorphous silicon, polysilicon, or low temperature polysilicon (LTPS), but embodiments of the disclosure are not limited thereto. The first transistor TFT1 may be implemented as a p-channel transistor or an n-channel thin film transistor, but embodiments of the disclosure are not limited thereto.

The first electrode E1a may be a gate electrode, the second electrode E1b may be a source electrode or a drain electrode, and the third electrode E1c may be a drain electrode or a source electrode. Hereinafter, for convenience of description, the first electrode E1a is referred to as a first gate electrode E1a, the second electrode E1b is referred to as a first source electrode E1b, and the third electrode E1c is referred to as a first drain electrode E1c, but embodiments of the disclosure are not limited thereto. However, embodiments of the disclosure are not limited thereto.

The second transistor TFT2 may include a second active layer ACT2, a fourth electrode E2a, a fifth electrode E2b, and a sixth electrode E2c. The second active layer ACT2 may be a second semiconductor layer, but embodiments of the disclosure are not limited thereto. For example, the second active layer ACT2 may be formed of an oxide semiconductor, amorphous silicon, polysilicon, or low temperature polysilicon (LTPS), but embodiments of the disclosure are not limited thereto. The second transistor TFT2 may be implemented as a p-channel transistor or an n-channel thin film transistor, but embodiments of the disclosure are not limited thereto.

For example, one of the first transistor TFT1 and the second transistor TFT2 may constitute an oxide semiconductor as an active layer. As another example, one of the first transistor TFT1 and the second transistor TFT2 may use low-temperature polysilicon as an active layer. As another example, the first transistor TFT1 and the second transistor TFT2 may configure an oxide semiconductor as an active layer. As another example, the first transistor TFT1 and the second transistor TFT2 may configure low-temperature polysilicon as an active layer. As another example, of the first transistor TFT1 and the second transistor TFT2, the driving transistor DT may configure an oxide semiconductor as an active layer, and the scan transistor ST may configure low-temperature polysilicon as an active layer. As another example, of the first transistor TFT1 and the second transistor TFT2, the driving transistor DT may configure low-temperature polysilicon as an active layer, and the scan transistor ST may configure an oxide semiconductor as an active layer. As another example, a transistor included in a gate driving circuit 140 of a gate in panel (GIP) type may configure an oxide semiconductor or low-temperature polysilicon as an active layer. As another example, all the transistors configured on the substrate 111 and transistors included in a gate driving circuit 130 of a gate in panel (GIP) type may configure an oxide semiconductor as an active layer.

The fourth electrode E2a may be a gate electrode, the fifth electrode E2b may be a source electrode or a drain electrode, and the sixth electrode E2c may be a drain electrode or a source electrode. Hereinafter, for convenience of description, the fourth electrode E2a is referred to as a second gate electrode E2a, the fifth electrode E2b is referred to as a second source electrode E2b, and the sixth electrode E2c is referred to as a second drain electrode E2c. However, embodiments of the disclosure are not limited thereto.

The second active layer ACT2 of the second transistor TFT2 may be positioned higher from the substrate 111 than the first active layer ACT1 of the first transistor TFT1.

The first buffer layer 311 may be disposed under the first active layer ACT1 of the first transistor TFT1, and a second buffer layer 321 may be disposed under the second active layer ACT2 of the second transistor TFT2. For example, the first active layer ACT1 of the first transistor TFT1 may be positioned on the first buffer layer 311, and the second active layer ACT2 of the second transistor TFT2 may be positioned on the second buffer layer 321. The second buffer layer 321 may be positioned higher than the first buffer layer 311.

The storage capacitor Cst may be disposed in various metal layers in the display panel 110. For example, the storage capacitor Cst may include a first capacitor electrode CAPE1 and a second capacitor CAPE2.

The light emitting element forming unit may include a plurality of light emitting elements ED disposed on at least one planarization layer 331 and 332. Each of the plurality of light emitting elements ED may include a pixel electrode PE, an intermediate layer EL, and a common electrode CE.

The encapsulation unit may include an encapsulation layer 200 on the plurality of light emitting elements ED. The encapsulation layer 200 may be a single layer or multiple layers. The encapsulation portion may further include a dam DAM in addition to the encapsulation layer 200.

Hereinafter, a vertical structure of the display panel 110 according to embodiments of the disclosure is described in more detail with reference to FIG. 3.

Referring to FIG. 3, the first buffer layer 311 may be disposed on the substrate 111. The first buffer layer 311 may be a single layer or multiple layers. When the first buffer layer 311 includes multiple layers, the first buffer layer 311 may include a multi-buffer layer 311a and an active buffer layer 311b.

The multi-buffer layer 311a may be an inorganic insulation layer. The multi-buffer layer 311a may block or delay diffusion of the moisture and/or oxygen penetrating the substrate 111. For example, the multi-buffer layer 311a may be formed of a single layer of silicon nitride (SiNx), silicon oxide (SiOx), or silicon oxynitride (SiOxNy), or multiple layers thereof, but is not limited thereto.

The active buffer layer 311b may be an inorganic insulation layer. The active buffer layer 311b may protect the first active layer ACT1 and may perform the function of blocking or delaying various types of defects introduced from the substrate 111. For example, the active buffer layer 311b may be formed of a single layer of amorphous silicon (a-Si), silicon nitride (SiNx), or silicon oxide (SiOx), or multiple layers thereof, but is not limited thereto.

The first active layer ACT1 of the first transistor TFT1 may be disposed on the first buffer layer 311. The first active layer ACT1 may include a channel area in which a channel is formed, a source connection area on one side of the channel area, and a drain connection area on the other side of the channel area.

The first gate insulation layer 312 may be disposed on the first active layer ACT1 of the first transistor TFT1. The first gate insulation layer 312 may be formed of a single layer of silicon nitride (SiNx) or silicon oxide (SiOx) or multiple layers thereof, but is not limited thereto. The first gate electrode E1a of the first transistor TFT1 may be disposed on the first gate insulation layer 312.

The first inter-layer insulation layer 313 may be disposed on the first gate electrode E1a of the first transistor TFT1. The first interlayer insulation layer 313 may be formed of a single layer of silicon nitride (SiNx) or silicon oxide (SiOx) or multiple layers thereof, but is not limited thereto.

The second buffer layer 321 may be disposed on the first inter-layer insulation layer 313. The second buffer layer 321 may be formed of a single layer of silicon nitride (SiNx) or silicon oxide (SiOx) or multiple layers thereof, but is not limited thereto.

The second active layer ACT2 of the second transistor TFT2 may be disposed on the second buffer layer 321. The second active layer ACT2 may include a channel area in which a channel is formed, a source connection area on one side of the channel area, and a drain connection area on the other side of the channel area.

The second gate insulation layer 322 may be disposed on the second active layer ACT2 of the second transistor TFT2. The second gate insulation layer 322 may be formed of a single layer of silicon nitride (SiNx) or silicon oxide (SiOx) or multiple layers thereof, but is not limited thereto. The second gate electrode E2a of the second transistor TFT2 may be disposed on the second gate insulation layer 322.

The second inter-layer insulation layer 323 may be disposed on the second gate electrode E2a of the second transistor TFT2. The second interlayer insulation layer 323 may be formed of a single layer of silicon nitride (SiNx) or silicon oxide (SiOx) or multiple layers thereof, but is not limited thereto.

The first source electrode E1b and the first drain electrode E1c of the first transistor TFT1, and the second source electrode E2b and the second drain electrode E2c of the second transistor TFT2 may be disposed on the second inter-layer insulation layer 323.

The first source electrode E1b and the first drain electrode E1c of the first transistor TFT1 may be connected to the source connection area and the drain connection area, respectively, of the first active layer ACT1 through contact holes of the second inter-layer insulation layer 323, the second gate insulation layer 322, the second buffer layer 321, the first inter-layer insulation layer 313, and the first gate insulation layer 312.

The second source electrode E2b and the second drain electrode E2c of the second transistor TFT2 may be connected to the source connection area and the drain connection area, respectively, of the second active layer ACT2 through the contact holes of the second inter-layer insulation layer 323 and the second gate insulation layer 322.

The first source electrode E1b and the first drain electrode E1c of the first transistor TFT1, and the second source electrode E2b and the second drain electrode E2c of the second transistor TFT2 may include a first metal and may be disposed in the first metal layer. Here, the first metal and the first metal layer may be referred to as a first source-drain metal and a first source-drain metal layer.

Referring to FIG. 3, the storage capacitor Cst may be formed by a first capacitor electrode CAPE1 and a second capacitor electrode CAPE2. In some cases, the storage capacitor Cst may be formed by three or more capacitor electrodes or may have a form in which two or more capacitors are connected in parallel.

Each of the first capacitor electrode CAPE1 and the second capacitor electrode CAPE2 may be disposed on various metal layers disposed in the display panel 110.

For example, the first capacitor electrode CAPE1 may include the same first gate metal as the first gate electrode E1a of the first transistor TFT1 on the first gate insulation layer 312 and may be disposed in the first gate metal layer.

For example, the second capacitor electrode CAPE2 may be disposed on the first inter-layer insulation layer 313.

The second source electrode E2b of the second transistor TFT2 may be electrically connected to the second capacitor electrode CAPE2 through contact holes of the second inter-layer insulation layer 323, the second gate insulation layer 322, and the second buffer layer 321.

For example, the first transistor TFT1 may be the scan transistor ST of FIG. 2, and the second transistor TFT2 may be the driving transistor DT of FIG. 2.

The transistor forming unit may further include various metal patterns. For example, the first metal pattern may be disposed between the multi-buffer layer 311a and the active buffer layer 311b included in the first buffer layer 311. The second metal pattern may include the same first gate metal as the first gate electrode E1a of the first transistor TFT1, and may be disposed in the first gate metal layer. However, embodiments of the disclosure are not limited thereto.

Each of the first metal pattern MP1 and the second metal pattern MP2 may be disposed in the display area DA or the non-display area NDA.

Referring to FIG. 3, the transistor forming unit may further include a first shield metal BSM1 disposed on the substrate 111 and overlapping the first active layer ACT1 of the first transistor TFT1 and disposed under the first active layer ACT1 of the first transistor TFT1. For example, the first shield metal BSM1 may be disposed between the substrate 111 and the first buffer layer 311 or may be disposed between the multi-buffer layer 311a and the active buffer layer 311b.

The transistor forming unit may further include a second shield metal BSM2 disposed on the substrate 111 and overlapping the second active layer ACT2 of the second transistor TFT2 and disposed under the second active layer ACT2 of the second transistor TFT2.

For example, the second shield metal BSM2 may be disposed in a metal layer between the first insulation layer 313 and the second buffer layer 321. The second shield metal BSM2 may be disposed in the same metal layer as the second capacitor CAPE2.

As another example, the second shield metal BSM2 may be disposed in the same first gate metal layer as the first gate electrode E1a of the first transistor TFT1. Referring to FIG. 3, the transistor forming unit may further include a common driving voltage pattern to which a common driving voltage is applied. For example, the common driving voltage applied to the common driving voltage pattern may also be referred to as a power signal, and may be a first common driving voltage VDD or a second common driving voltage VSS. The first common driving voltage VDD may also be referred to as a high-potential power voltage (high-potential power signal), and the second common driving voltage VSS may also be referred to as a low-potential power voltage (low-potential power signal) or a base voltage.

The common driving voltage pattern may be disposed in the display area DA or the non-display area NDA.

At least one planarization layer may be disposed on the first transistor TFT1 and the second transistor TFT2. In some cases, three or more planarization layers may be disposed on the first transistor TFT1 and the second transistor TFT2, but embodiments of the disclosure are not limited thereto. The planarization pattern may be an organic insulation layer capable of performing a planarization function.

Referring to FIG. 3, the first planarization layer 331 may be disposed on the first source electrode E1b and the first drain electrode E1c of the first transistor TFT1, and the second source electrode E2b and the second drain electrode E2c of the second transistor TFT2. The first planarization layer 331 may be disposed while covering both the first transistor TFT1 and the second transistor TFT2. The first planarization layer 331 may be an organic insulation layer for planarizing and protecting the upper portions of the first transistor TFT1 and the second transistor TFT2. For example, the first planarization layer 331 may be formed of an organic insulating material such as acrylic resin, epoxy resin, phenolic resin, polyamide resin, polyimide resin, etc.

Referring to FIG. 3, various conductive patterns may be disposed on the first planarization layer 331. The conductive pattern may include a first conductive pattern, a second conductive pattern, and a third conductive pattern. The conductive pattern may be formed using a metal, an alloy, a metal nitride, a conductive metal oxide, or a transparent conductive material.

Referring to FIG. 3, a relay electrode RE may be disposed on the first planarization layer 331. The relay electrode RE may be a third conductive pattern. The relay electrode RE may be electrically connected to the second source electrode E2b of the second transistor TFT2 through the contact hole of the first planarization layer 331. Here, the second source electrode E2b of the second transistor TFT2 may be electrically connected to the second capacitor electrode CAPE2 of the storage capacitor Cst.

The relay electrode RE may be disposed in the second metal layer on the first planarization layer 331 and may include a second metal. The second metal and the second metal layer may be referred to as a second source-drain metal and a second source-drain metal layer.

The second planarization layer 332 may be disposed on the first planarization layer 331 and the relay electrode RE. For example, the second planarization layer 332 may be formed of an organic insulating material such as acrylic resin, epoxy resin, phenolic resin, polyamide resin, polyimide resin, etc.

Referring to FIG. 3, the light emitting element forming unit may be disposed on the second planarization layer 332. The light emitting element ED may be formed on the second planarization layer 332. The light emitting element ED may include a pixel electrode PE, an intermediate layer EL, and a common electrode CE. The emission area of the light emitting element ED may be formed in an area in which the pixel electrode PE, the intermediate layer EL, and the common electrode CE overlap and contact each other.

The pixel electrode PE may be disposed on the second planarization layer 332. The pixel electrode PE may be electrically connected to the relay electrode RE through the contact hole of the second planarization layer 332.

A bank layer 334 may be disposed on the pixel electrode PE. The opening (or open portion) of the bank layer 334 may expose a portion of the pixel electrode PE to form the emission area. For example, the opening of the bank layer 334 may overlap a portion of the pixel electrode PE. The bank layer 334 may be formed of an inorganic insulating material such as silicon nitride (SiNx) and silicon oxide (SiOx), or an organic insulating material such as benzocyclobutene resin, acrylic resin, or imide resin, but is not limited thereto. A spacer may be further disposed on the bank layer 334.

The intermediate layer EL of the light emitting element ED may be disposed on a portion of the pixel electrode PE and the bank layer 334. The common electrode CE may be disposed on the intermediate layer EL.

Referring to FIG. 3, the encapsulation unit may be disposed on the light emitting element forming unit and may be positioned on the common electrode CE. The encapsulation unit may include the encapsulation layer 200 formed on the common electrode CE.

The encapsulation layer 200 may prevent or at least reduce moisture or oxygen from penetrating into the light emitting element ED. For example, the encapsulation layer 200 may prevent moisture or oxygen from penetrating into the organic material included in the intermediate layer EL of the light emitting element ED. Here, the encapsulation layer 200 may be formed of a single layer or multiple layers, but embodiments of the disclosure are not limited thereto.

Referring to FIG. 3, the encapsulation layer 200 may include a first encapsulation layer 341, a second encapsulation layer 342, and a third encapsulation layer 343. For example, the first encapsulation layer 341 and the third encapsulation layer 343 may include an inorganic layer, and the second encapsulation layer 342 may include an organic layer.

The first encapsulation layer 341 may be disposed on the cathode electrode CE and be disposed closest to the light emitting element ED. The first encapsulation layer 341 may be formed of an inorganic insulating material capable of low temperature deposition. For example, the first encapsulation layer 341 may be silicon nitride (SiNx), silicon oxide (SiOx), silicon oxynitride (SiOxNy), or aluminum oxide (AlOx). Since the first encapsulation layer 341 is deposited in a low-temperature atmosphere, the first encapsulation layer 510 may prevent the intermediate layer EL including an organic material vulnerable to a high-temperature atmosphere from being damaged during the deposition process.

The second encapsulation layer 342 may serve as a buffer to relieve stress between layers due to bending of the display device and may also serve to enhance planarization performance. For example, the second encapsulation layer 342 may be formed of an organic insulating material such as an acrylic resin, an epoxy resin, polyimide, polyethylene, silicon oxycarbon (SiOC), or the like. For example, the second encapsulation layer 342 may be formed through an inkjet method, but is not limited thereto.

The third encapsulation layer 343 may be formed on the substrate 111 on which the second encapsulation layer 342 is formed to cover the upper surface and the side surface of each of the second encapsulation layer 342 and the first encapsulation layer 341. In this case, the third encapsulation layer 343 may minimize or block external moisture or oxygen from penetrating into the first encapsulation layer 341 and the second encapsulation layer 342. For example, the third encapsulation layer 343 may be formed of an inorganic insulating material such as silicon nitride (SiNx), silicon oxide (SiOx), silicon oxynitride (SiOxNy), or aluminum oxide (AlOx), but the disclosure is not limited thereto.

The display panel 110 according to embodiments of the disclosure may include a touch sensor. In this case, the display panel 110 according to embodiments of the disclosure may include a touch sensor layer 210 formed on the encapsulation layer 200.

Referring to FIG. 3, the touch sensor layer 210 may include a plurality of touch electrodes TE and may include a sensor metal TSM and a bridge metal BRG to form the plurality of touch electrodes TE. In embodiments of the disclosure, the sensor metal TSM is referred to as a sensor metal layer TSM, and the bridge metal BRG is referred to as a bridge metal layer BRG.

The touch sensor layer 210 may further include insulation layers such as a sensor buffer layer 351 on the encapsulation layer 200, a sensor interlayer insulation layer 352 on the sensor buffer layer 351, and a sensor protective layer 353 on the sensor interlayer insulation layer 352. Here, the sensor buffer layer 351 may be omitted.

A bridge metal BRG may be disposed between the sensor buffer layer 351 and the sensor interlayer insulation layer 352, and the sensor metal TSM may be disposed between the sensor interlayer insulation layer 352 and the sensor protective layer 353.

The sensor buffer layer 351 may be disposed on the encapsulation layer 200. The sensor buffer layer 351 may serve to prevent or at least reduce damage to the encapsulation layer 200 and block interference signals to the touch electrode TE by the signals of the transistors TFT1 and TFT2. The sensor buffer layer 351 may facilitate formation of the touch electrode TE on the encapsulation layer 200 and enhance the adhesion between the touch electrode TE and the encapsulation layer 200. The sensor buffer layer 351 may be an inorganic insulation layer. For example, the sensor buffer layer 351 may include an inorganic insulating material, such as silicon oxide (SiOx), silicon nitride (SiNX), or silicon oxynitride (SiOxNy), and may be formed of a single layer or multiple layers, but the disclosure is not limited thereto.

The sensor buffer layer 351 may be disposed on the encapsulation layer 200. The sensor buffer layer 351 may facilitate formation of the touch electrode TE on the encapsulation layer 200 and enhance the force by which the touch electrode TE is fixed onto the encapsulation layer 200. The sensor buffer layer 351 may be an organic insulation layer. For example, the sensor buffer layer 351 may be formed of an acrylic-based, epoxy-based, or siloxane-based material, but the disclosure is not limited thereto.

Each of the plurality of touch electrodes TE may be formed of a sensor metal TSM. Each of the plurality of touch electrodes TE may be a mesh-type electrode having a plurality of openings.

The plurality of touch electrodes TE may include a first touch electrode TE1 and a second touch electrode TE2. The sensor metal TSM included in the first touch electrode TE1 may be electrically connected through the bridge metal BRG. In other words, the sensor metals TSM spaced apart from each other may be electrically connected by the bridge metal BRG to constitute one first touch electrode TE1.

The bridge metal BRG may be disposed on the sensor buffer layer 351, and the sensor interlayer insulation film 352 may be disposed on the bridge layers BRG. The sensor interlayer insulation layer 352 may be an inorganic insulation layer. For example, the sensor interlayer insulation layer 352 may be formed of silicon nitride (SiNx), silicon oxide (SiOx), silicon oxynitride (SiOxNy), titanium oxide (TiOx), or aluminum oxide (AlOx), but the disclosure is not limited thereto.

The sensor metal TSM may be disposed on the sensor interlayer insulation layer 352. A portion of the sensor metal TSM may be connected to the corresponding bridge metal BRG through the contact hole of the sensor interlayer insulation layer 352.

Referring to FIG. 3, the sensor metal TSM and the bridge metal BRG may be disposed not to overlap the light emitting element ED. The sensor metal TSM and the bridge metal BRG may overlap the bank layer 334.

The plurality of sensor metals TSM may configure one touch electrode and may be disposed in a mesh form and electrically connected. A portion of the sensor metal TSM and another portion of the sensor metal TSM may be electrically connected through the bridge metal BRG to constitute one touch electrode TE.

The sensor protective layer 353 may be disposed while covering the sensor metal TSM and the bridge metal BRG. The sensor protective layer 353 may be an organic insulation layer. Such an organic insulation layer may be the same material as the above-described planarization layers 331 and 332, for example. The organic insulation layer may be formed of a material different from that of the second encapsulation layer 342. For example, the sensor protective layer 353 may be formed of a photocurable organic material, such as an acrylic material, a polyimide material, or a siloxane material, but is not limited thereto.

Referring to FIG. 3, the touch line TL may electrically connect the touch electrode TE to the touch pad TP. The touch line TL may be formed of at least one of the sensor metal TSM and the bridge metal BRG.

When the display panel 110 is of a type in which a touch sensor is embedded, the touch line TL may extend along the outer inclined surface SLP_ENCAP of the encapsulation layer 200 and may extend beyond the upper portion of a dam DAM to the touch pad TP in the non-display area NDA.

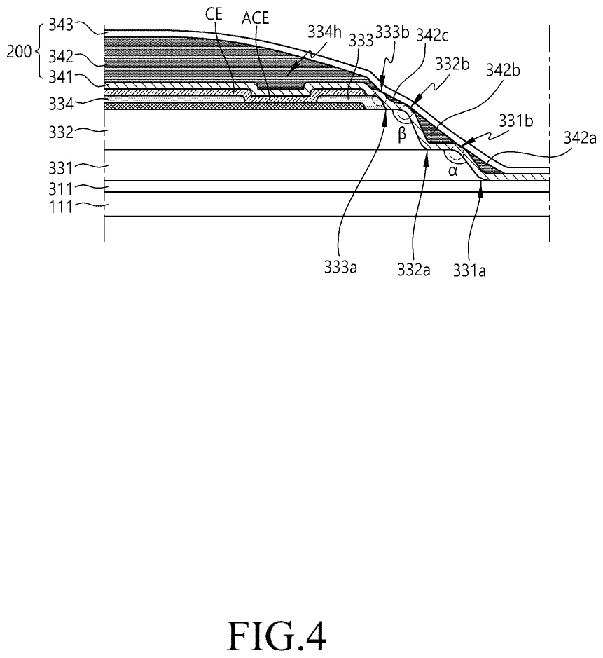

FIG. 4 is a cross-sectional view according to an embodiment of the disclosure. Features that are identical or similar to those described with reference to FIGS. 1 to 3 are omitted from the following description or briefly described below.

FIG. 4 illustrates the first to second planarization layers 331 and 332 disposed in the non-display area NDA, the auxiliary connection electrode ACE, the bank pattern 333, the common electrode CE, and the encapsulation layer 200 among the various components described above in FIG. 3.

Referring to FIG. 4, the first planarization layer 331 and the second planarization layer 332 may be disposed on the buffer layer 311, but the disclosure is not limited thereto. The planarization layer may be formed of a single layer or two or more layers. At least a portion of the upper surface of the first planarization layer 331 may not overlap the second planarization layer 332. The shapes of the first and second planarization layers 331 and 332 may be represented as a step or a step shape.

Side surfaces of the first and second planarization layers 331 and 332 may be formed at various angles. For example, a side surface of the first planarization layer 331 may form an obtuse angle with an upper surface of the first planarization layer 331. Further, the side surface of the first planarization layer 331 may form an acute angle with the upper surface of the first planarization layer 331. Likewise, when the side surface of the first planarization layer 331 forms an obtuse angle with the upper surface of the first planarization layer 331, the upper surface of the second planarization layer 332 may form an obtuse angle with the side surface of the second planarization layer 332, but the disclosure is not limited thereto. The upper surfaces of the first and second planarization layers 331 and 332 and the respective side surfaces thereof may form an obtuse angle or an acute angle as necessary.

Referring to FIG. 4, protrusions 331b and 332b and stepped portions 331a and 332a may be positioned at ends of the planarization layers 331 and 332. Here, the ends of the planarization layers 331 and 332 may mean portions of the planarization layers 331 and 332 facing the outermost area of the non-display area. The protrusions 331b and 332b facing the outermost area of the non-display area NDA of the display device may be positioned over the ends of the planarization layers 331 and 332, and the stepped portions 331a and 332a may be positioned under the ends of the planarization layers 331 and 332.

Referring to FIG. 4, the protrusions 331b and 332b may be positioned at portions where upper and side surfaces of the planarization layers 331 and 332 contact each other. For example, the first protrusion 331b may be positioned at the portion where the upper surface and the side surface of the first planarization layer 331 contact each other. The second protrusion 332b may be positioned at the portion where the upper surface and the side surface of the second planarization layer 332 contact each other.

Referring to FIG. 4, the stepped portions 331a and 332a may be positioned under the side surfaces of the planarization layers 331 and 332. The stepped portions 331a and 332a may be positioned at the portions where the side surfaces of the planarization layers 331 and 332 and the upper surface of the layer positioned under the planarization layers 331 and 332 contact each other. For example, the first stepped portion 331a may be positioned at the portion where the upper surface of the buffer layer 311 contacts the side surface of the first planarization layer 331. The second stepped portion 332a may be positioned at the portion where the upper surface of the first planarization layer 331 and the side surface of the second planarization layer 332 meet.

An auxiliary connection electrode ACE, a bank pattern 333, and a common electrode CE may be sequentially disposed on the first and second planarization layers 331 and 332.

The auxiliary connection electrode ACE may be formed of the same material as the pixel electrode PE. Specifically, the auxiliary connection electrode ACE may be formed of the same material as the anode, but the disclosure is not limited thereto. The auxiliary connection electrode ACE may have the same meaning as the first electrode and the anode.

The bank layer 334 disposed in the non-emission area may include a bank hole 334h and a bank pattern 333. The bank pattern 333 surrounding the bank hole 334h in the bank layer 334 may be disposed to overlap an upper surface of the first planarization layer 331 and at least a portion of the auxiliary connection electrode ACE. The bank pattern 333 may be disposed in a ring shape in the non-emission area.

Referring to FIG. 4, a third protrusion 333b and a third stepped portion 333a may be positioned at an end of the bank pattern 333. Here, the end of the bank pattern 333 may mean a portion of the bank pattern 333 facing the outermost area of the non-display area. The third protrusion 333b may be positioned over the end of the bank pattern 333, and the third stepped portion 333a may be positioned under the end of the bank pattern 333.

Referring to FIG. 4, the third protrusion 333b may be positioned at the portion where the upper surface and the side surface of the bank pattern 333 contact each other. The third stepped portion 333a may be positioned under the side surface of the bank pattern 333. The third stepped portion 333a may be positioned at the portion where the side surface of the bank pattern 333 contacts the upper surface of the layer positioned under the bank pattern 333. The third stepped portion 333a may be positioned at the portion where the upper surface of the second planarization layer 332 meets the side surface of the bank pattern 333.

The first encapsulation layer 341 may be disposed to overlap the bank layer 334 and the common electrode CE. Referring to FIG. 4, the first encapsulation layer 341 may be disposed to overlap the upper surface and the side surface of the bank pattern 333, a portion of the upper surface, and the side surface, of the second planarization layer 332, and a portion of the upper surface, and the side surface, of the first planarization layer 331, and the buffer layer 311.

The common electrode CE may have the same meaning as the second electrode and the cathode.

The first encapsulation layer 341 may be disposed to overlap at least a portion of upper surfaces of the first and second planarization layers 331 and 332. Further, the first encapsulation layer 341 may be disposed to overlap the side surfaces of the first and second planarization layers 331 and 332.

The second encapsulation layer 342 may be disposed to overlap at least a portion of the first encapsulation layer 341. In other words, the second encapsulation layer 342 may expose the first encapsulation layer 341 at portions corresponding to the first protrusion 331b, the second protrusion 332b, and the third protrusion 333b. The second encapsulation layer 342 may be controlled to be disposed only on the upper surface of the bank pattern 333.

The second encapsulation layer 342 may be disposed between at least a portion of the first to third stepped portions 331a, 332a and 333a and the third encapsulation layer 343. Accordingly, the overflowed second encapsulation layer 342 may be disposed to correspond between at least a portion of the first to third stepped portions 331a, 332a, and 333a formed in a step shape and the third encapsulation layer 343 so that the flow may be controlled.

Referring to FIG. 4, pattern portions 342a, 342b, and 342c may be disposed to respectively correspond to the stepped portions 331a, 332a, and 333a. In the pattern portions 342a, 342b and 342c, a portion of the second encapsulation layer 342 may be positioned in a pattern shape between the stepped portions 331a, 332a and 333a and the third encapsulation layer 343.

For example, the first pattern portion 342a may be disposed between the first stepped portion 331a and the third encapsulation layer 343. The second pattern portion 342b may be disposed between the second stepped portion 332a and the third encapsulation layer 343. The third pattern portion 342c may be disposed between the third stepped portion 333a and the third encapsulation layer 343. On the plane, each of the pattern portions 342a, 342b, and 342c may be disposed in a curved or straight line shape. On the plane, each of the pattern portions 342a, 342b, and 342c may have a closed-circuit shape that is continuously disposed. Further, on the plane, each of the pattern portions 342a, 342b, and 342c may have a disconnected shape. Meanwhile, in FIG. 4, three pattern portions 342a, 342b, and 342c are illustrated, but some of them may be disposed while others are not disposed.

The third encapsulation layer 343 may be formed to cover the first encapsulation layer 341 and the second encapsulation layer 342. Further, the third encapsulation layer 343 may contact the first encapsulation layer 341 at a portion corresponding to the first to third protrusions 331b, 332b, and 333b.

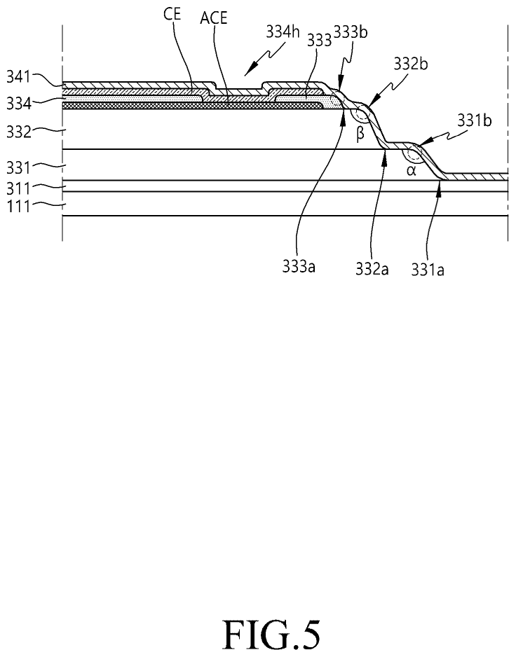

FIGS. 5 to 8 are example cross-sectional views illustrating a process of forming the display panel shown in FIG. 4 according to one embodiment. Features identical or similar to what has been described with reference to FIGS. 1 to 4 are omitted from the following description or are briefly described.

Referring to FIG. 5, a display device may include planarization layers 331 and 332, a bank layer 334, an auxiliary connection electrode ACE, a bank pattern 333, a common electrode CE, and a first encapsulation layer 341 disposed in the non-display area.

The auxiliary connection electrode ACE may be formed of the same material as the pixel electrode PE. Specifically, the auxiliary connection electrode ACE may be formed of the same material as the anode, but the disclosure is not limited thereto. The auxiliary connection electrode ACE may have the same meaning as the first electrode and the anode.

The common electrode CE may have the same meaning as the second electrode and the cathode.

The first encapsulation layer 341 may be disposed to overlap the first and second planarization layers 331 and 332, the pixel electrode PE, the bank pattern 333, and the common electrode CE. Further, the first encapsulation layer 341 may be disposed along the shape of the first and second planarization layers 331 and 332 formed as a step or a step shape. In this case, the planarization layers 331 and 332 may be formed of a single layer or the plurality of layers of two or more layers.

The first encapsulation layer 341 may contact the third encapsulation layer 343 at portions corresponding to the first to third protrusions 331b, 332b and 333b. Specifically, a first protrusion 331b formed at a portion where the upper surface and the side surface of the first planarization layer 331 meet, a second protrusion 332b formed at a portion where the upper surface and the side surface of the second planarization layer 332 meet, and a third protrusion 333b formed at a portion where the upper surface and the side surface of the bank pattern 333 meet may be included. Although not illustrated in FIG. 5, there may be an additional protrusion of the first encapsulation layer 341 overlapping the portion where the upper and side surfaces of the common electrode CE meet.

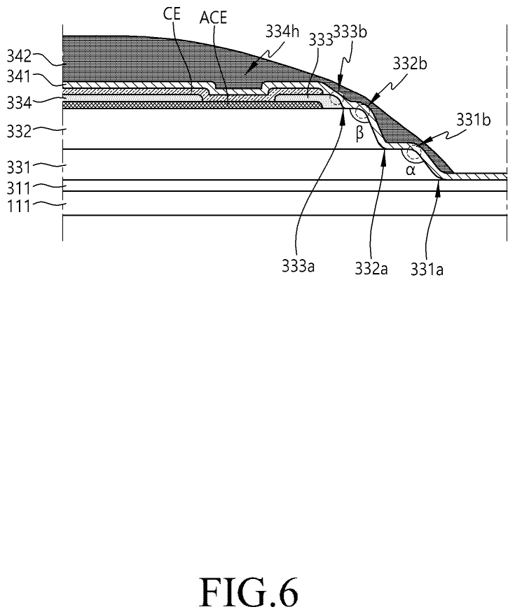

FIG. 6 is the cross-sectional view of the display panel of FIG. 5 in which the second encapsulation layer 342 is applied according to one embodiment. The second encapsulation layer 342 may be disposed along the upper surface and the side surface of the first encapsulation layer 341 formed on the side surfaces of the first and second planarization layers 331 and 332 and the bank pattern 333. The second encapsulation layer 342 may be controlled to overlap the upper surface of the first encapsulation layer 341 disposed on the upper surface of the bank pattern 333. In FIG. 6, the second encapsulation layer 342 is formed to overlap the upper surface of the first encapsulation layer 341 disposed on the buffer layer 311, but the disclosure is not limited thereto. The second encapsulation layer 342 may be controlled between the first encapsulation layer 341 disposed on the upper surface of the bank pattern 333 and the third encapsulation layer 343 disposed on the upper surface of the buffer layer 311.

The second encapsulation layer 342 may be disposed to cover an upper surface of the first encapsulation layer 341. The second encapsulation layer 342 may be formed to cover any one portion of the upper surface of the first encapsulation layer 341 so as to correspond to at least any one of the first to third protrusions 331b, 332b and 333b. Accordingly, the overflowed second encapsulation layer 342 may be formed at portions corresponding to the first to third stepped portions 331a, 332a and 333a formed in a step shape. Specifically, the first stepped portion 331a may be formed at the portion where the upper surface of the buffer layer 311 and the side surface of the first planarization layer 331 contact each other, the second stepped portion 332a may be formed at the portion where the upper surface of the first planarization layer 331 and the side surface of the second planarization layer 332 contact each other, and the third stepped portion 333a may be formed at the portion where the upper surface of the second planarization layer 332 and the side surface of the bank pattern 333 contact each other. The second encapsulation layer 342 formed to correspond to at least a portion of the first to third stepped portions 331a, 332a and 333a may be controlled not to overflow.

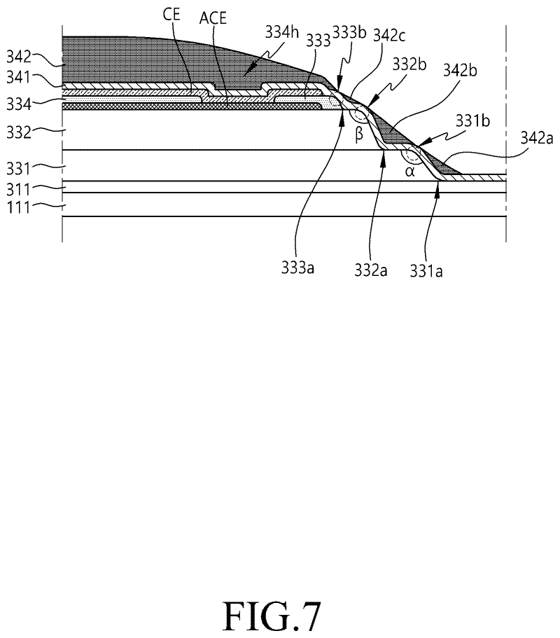

FIG. 7 is the cross-sectional view of the display panel of FIG. 6 after an ashing process is performed according to one embodiment. As illustrated in FIG. 6, when the second encapsulation layer 342 is at least partially connected on the first to third protrusions 331b, 332b and 333b, it may function as a moisture entry path. Specifically, when the second encapsulation layer 342 is formed at the portion corresponding to at least a portion of the first to third protrusions 331b, 332b, and 333b, moisture may penetrate along the path of the second encapsulation layer 342. In order to prevent moisture penetration mentioned, the disclosure may additionally perform an ashing process after applying the second encapsulation layer 342.

Referring to FIG. 7, the second encapsulation layer 342 may be subjected to an ashing process so that at least a portion of the first encapsulation layer 341 is exposed at positions corresponding to the first to third protrusions 331b, 332b and 333b. Specifically, the overflowed second encapsulation layer 342 may be cut off by the exposed portion of the first encapsulation layer 341 at the position corresponding to the first to third protrusions 331b, 332b, and 333b to form an island shape. Accordingly, it is possible to block the entry of moisture through the second encapsulation layer 342. After the ashing process, the second encapsulation layer 342 may be formed to correspond to the first to third stepped portions 331a, 332a and 333a. Specifically, after the ashing process, the second encapsulation layer 342 may be disposed between at least a portion of the first to third stepped portions 331a, 332a and 333a and the third encapsulation layer 343. Further, the third encapsulation layer 343 may contact the first encapsulation layer 341 at a portion corresponding to the first to third protrusions 331b, 332b, and 333b.

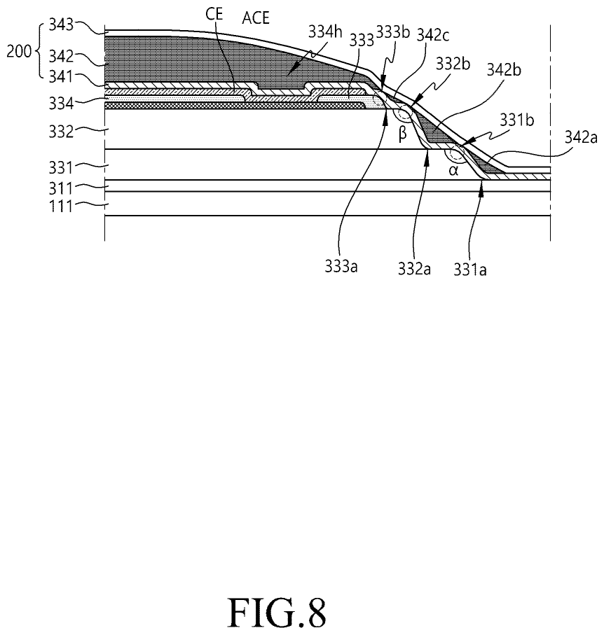

The second encapsulation layer 342 may include first to third pattern portions 342a, 342b and 342c. The first pattern portion 342a may be disposed between the first stepped portion 331a and the third encapsulation layer 343, the second pattern portion 342b may be disposed between the second stepped portion 332a and the third encapsulation layer 343, and the third pattern portion 342c may be disposed between the third stepped portion 333a and the third encapsulation layer 343. The shapes of the first to third pattern portions 342a, 342b and 342c of the second encapsulation portion 342 may be formed in a curved or straight line, but are not limited to it. Further, in FIG. 8, all of the of the first to third pattern portions 342a, 342b, and 342c are illustrated, but the disclosure is not limited thereto. For example, an embodiment of the disclosure may include at least a portion of the first pattern portion 342a, the second pattern portion 342b, and the third pattern portion 342c.

FIG. 8 is a view illustrating an example in which a third encapsulation layer 343 is applied after the ashing process of FIG. 7 according to one embodiment. The third encapsulation layer 343 may be formed to cover the first encapsulation layer 341 and the second encapsulation layer 342. Further, the third encapsulation layer 343 may contact the first encapsulation layer 341 at a portion corresponding to the first to third protrusions 331b, 332b, and 333b. The second encapsulation layer 342 may be formed at portions corresponding to the first to third stepped portions 331a, 332a and 333a formed in a step shape. In other words, an ashing process may be performed so that the second encapsulation layer 342 is not formed at the portions corresponding to the first to third protrusions 331b, 332b and 333b.

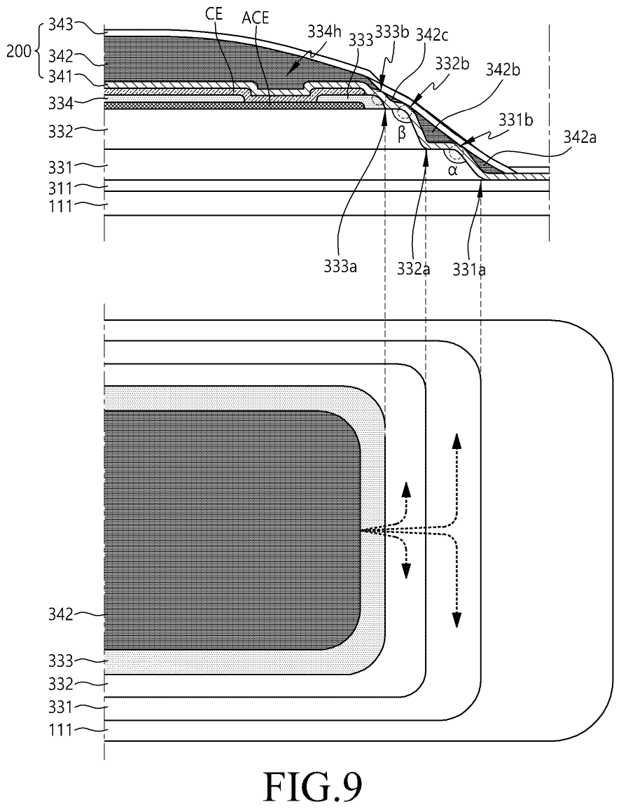

FIG. 9 is a plan view of the display panel of FIG. 4 according to one embodiment. As illustrated in FIG. 9, the second encapsulation layer 342 may be controlled not to exceed the bank pattern 333. Meanwhile, the second encapsulation layer 342 may overflow beyond the bank pattern 333, and in this case, the second encapsulation layer 342 may overflow at least one side surface among the first side surface to the fourth side surface of the non-display area NDA.

When overflowing, any one portion of the second encapsulation layer 342 may surpass the bank pattern 333 to overlap or contact the first encapsulation layer 341 disposed on the upper and side surface of at least one of the first and second planarization layers 331 and 332.

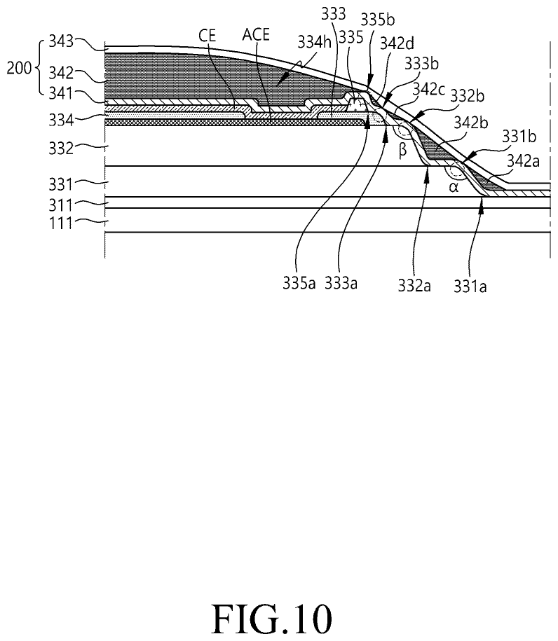

FIG. 10 is a cross-sectional view of a display panel according to another embodiment of the disclosure. In FIG. 10, a spacer 335 may be added and disposed in the embodiment of FIG. 4. Features that are identical or similar to those described with reference to FIGS. 1 to 4 are omitted from the following description or briefly described below.

Referring to FIG. 10, a spacer 335 may be disposed on the bank pattern 333. The spacer 335 may be formed of the same or similar material as or to the material forming the bank layer 334 or the bank pattern 333. For example, the spacer 335 may be formed of an inorganic insulating material such as silicon nitride (SiNx) or silicon oxide (SiOx) or an organic insulating material such as benzocyclobutene resin, acrylic resin, or imide resin, but the disclosure is not limited thereto.

The side surface of the spacer 335 and the side surface of the bank pattern 335 disposed in the non-display area do not overlap each other, forming a step or a step shape therebetween.

Referring to FIG. 10, a fourth protrusion 335b and a fourth stepped portion 335a may be positioned at an end of the spacer 335. The third protrusion 333b and the third stepped portion 333a may be positioned at an end of the spacer 335. Here, the end of the spacer 335 may mean a portion of the spacer 335 facing the outermost area of the non-display area. The fourth protrusion 335b may be positioned over the end of the spacer 335, and the fourth stepped portion 335a may be positioned under the end of the spacer 335.

Referring to FIG. 10, the fourth protrusion 335b may be positioned at the portion where the upper surface and the side surface of the spacer 335 contact each other. The fourth stepped portion 335a may be positioned under the side surface of the spacer 335. The fourth stepped portion 335a may be positioned at the portion where the side surface of the spacer 335 contacts the upper surface of the layer positioned under the spacer 335. The fourth stepped portion 335a may be positioned at the portion where the upper surface of the bank pattern 333 meets the side surface of the spacer 335.

The first encapsulation layer 341 may form portions protruding from the portions corresponding to the first to fourth protrusions 331b, 332b, 333b and 335b. In the other embodiment of FIG. 10, as the spacer 335 is further disposed as compared with the embodiment of FIG. 4, a fourth protrusion 335b overlapping the portion where the upper and side surfaces of the spacer 335 meet may be further included. Further, a fourth stepped portion 335a formed at the portion where the upper surface of the bank pattern 333 and the side surface of the spacer 335 contact may be further disposed. As the fourth stepped portion 335a is disposed by the spacer 335, the flow of the second encapsulation layer 342 may be controlled once more in the fourth stepped portion 335a, so that the moisture proofing capacity may be enhanced compared to the embodiment of FIG. 4. Specifically, as the spacer 335 is disposed as disclosed in FIG. 10, the fourth pattern portion 342d may be further disposed by the second encapsulation layer 342 than the embodiment of FIG. 4. As the fourth pattern portion 342d is added, the overflow of the second encapsulation layer 342 may be delayed, and thus control may be facilitated. Although not disclosed in FIG. 10, there may further be a corner of the first encapsulation layer 341 overlapping the portion where upper and side surfaces of the common electrode CE meet.

The second encapsulation layer 342 may be disposed between at least a portion of the first to fourth stepped portions 331a, 332a, 333a and 335a and the third encapsulation layer 343. Accordingly, the overflowed second encapsulation layer 342 may be formed on portions corresponding to the first to fourth stepped portions 331a, 332a, 333a and 335a of the first encapsulation layer formed in a step shape.

Referring to FIG. 10, the fourth pattern portion 342d may be disposed to correspond to the fourth stepped portion 335a. In the fourth pattern portion 342d, a portion of the second encapsulation layer 342 may be positioned in a pattern shape between the fourth stepped portion 335a and the third encapsulation layer 343.

On the plane, each of the first to fourth pattern portions 342a, 342b, 342c and 342d may be disposed in a curved or straight line shape, but the disclosure is not limited thereto. On the plane, each of the first to fourth pattern portions 342a, 342b, 342c and 342d may have a closed circuit shape that is continuously disposed. Further, on the plane, each of the first to fourth pattern portions 342a, 342b, 342c, and 342d may have a disconnected shape. Further, in FIG. 10, all of the of the first to fourth pattern portions 342a, 342b, 342c, and 342d are illustrated, but the disclosure is not limited thereto. For example, an embodiment of the disclosure may include at least one of the first pattern portion 342a, the second pattern portion 342b, the third pattern portion 342c, and the fourth pattern portion 342d.

The third encapsulation layer 343 may be formed to cover the first encapsulation layer 341 and the second encapsulation layer 342. Further, the third encapsulation layer 343 may contact the first encapsulation layer 341 at the portions corresponding to the first to fourth protrusions 331b, 332b, 333b, and 335b.

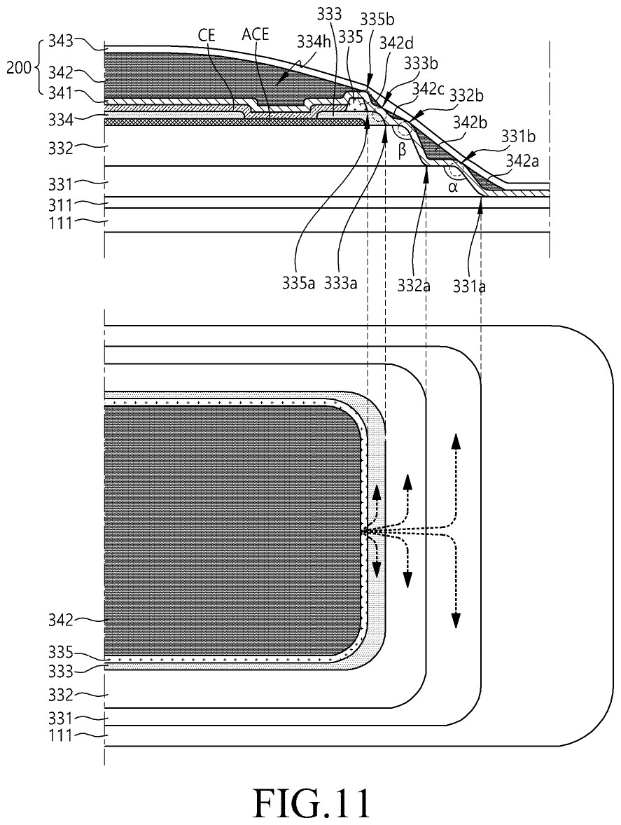

FIG. 11 is a plan view of the display panel shown in FIG. 10 according to another embodiment. The spacer 335 may be disposed on the bank pattern 335. Specifically, the spacer 335 may be formed to form a step shape or a step with the bank pattern 333.

As illustrated in FIG. 11, the second encapsulation layer 342 may be controlled not to exceed the spacer 335. Meanwhile, the second encapsulation layer 342 may overflow the spacer 335, and in this case, the second encapsulation layer 342 may overflow to at least one side surface among the first to fourth side surfaces of the non-display area NDA.

A display device according to embodiments of the disclosure may comprise a substrate including an emission area and a non-emission area, a buffer layer disposed on the substrate, a first planarization layer and a second planarization layer disposed on the buffer layer, a bank pattern disposed on the second planarization layer in the non-emission area, a first encapsulation layer overlapping an upper surface and a side surface of each of the bank pattern, the first planarization layer, and the second planarization layer, a first protrusion formed at a portion where the upper surface and side surface of the first planarization layer contact, a second protrusion formed at a portion where the upper surface and side surface of the second planarization layer contact, a third protrusion formed at a portion where the upper surface and side surface of the bank pattern contact, a second encapsulation layer disposed on the first encapsulation layer, wherein at least a portion of the first encapsulation layer corresponds to the first protrusion, the second protrusion, and the third protrusion, and a third encapsulation layer disposed on the second encapsulation layer. The third encapsulation layer may contact the first encapsulation layer corresponding to the first protrusion, the second protrusion, and the third protrusion.

In the display device according to embodiments of the disclosure, an angle between the upper surface of the first and second planarization layers and the side surface of each of the first and second planarization layers may be an obtuse angle.

In the display device according to embodiments of the disclosure, an angle between the upper surface of the first and second planarization layers and the side surface of each of the first and second planarization layers may be an acute angle.

The display device according to embodiments of the disclosure may comprise a first stepped portion formed at a portion where an upper surface of the buffer layer and the side surface of the first planarization layer contact, a second stepped portion formed at a portion where the upper surface of the first planarization layer and the side surface of the second planarization layer contact, and a third stepped portion formed at a portion where the upper surface of the second planarization layer and the side surface of the bank pattern contact, at least a portion of the first encapsulation layer corresponds to the first stepped portion, the second stepped portion, and the third stepped portion. At least a portion of the first encapsulation layer may correspond to the first stepped portion, the second stepped portion, and the third stepped portion.

In the display device according to embodiments of the disclosure, the second encapsulation layer may be disposed between at least a portion of the first stepped portion, the second stepped portion, and the third stepped portion and the third encapsulation layer.

In the display device according to embodiments of the disclosure, the second encapsulation layer may include a first pattern portion, a second pattern portion, and a third pattern portion. The first pattern portion may be disposed between the first stepped portion and the third encapsulation layer, the second pattern portion may be disposed between the second stepped portion and the third encapsulation layer, and the third pattern portion may be disposed between the third stepped portion and the third encapsulation layer.

The display device according to embodiments of the disclosure may comprise a spacer disposed on the bank pattern. A side surface of the spacer and the side surface of the bank pattern may not overlap each other.

The display device according to embodiments of the disclosure may comprise a fourth protrusion formed at a portion where an upper surface and a side surface of the spacer contact. At least a portion of the first encapsulation layer may correspond to the fourth protrusion. The third encapsulation layer may contact the first encapsulation layer corresponding to the fourth protrusion.

The display device according to embodiments of the disclosure may comprise a first stepped portion formed at a portion where an upper surface of the buffer layer and the side surface of the first planarization layer contact, a second stepped portion formed at a portion where the upper surface of the first planarization layer and the side surface of the second planarization layer contact, a third stepped portion formed at a portion where the upper surface of the second planarization layer and the side surface of the bank pattern contact, and a fourth stepped portion formed at a portion where the upper surface of the bank pattern and the side surface of the spacer contact. At least a portion of the first encapsulation layer may correspond to the first stepped portion, the second stepped portion, the third stepped portion, and the fourth stepped portion.

In the display device according to embodiments of the disclosure, the second encapsulation layer may be disposed between at least a portion of the first stepped portion, the second stepped portion, the third stepped portion, and the fourth stepped portion and the third encapsulation layer.

In the display device according to embodiments of the disclosure, the second encapsulation layer may include a first pattern portion, a second pattern portion, a third pattern portion, and a fourth pattern portion. The first pattern portion may be disposed between the first stepped portion and the third encapsulation layer, the second pattern portion may be disposed between the second stepped portion and the third encapsulation layer, the third pattern portion may be disposed between the third stepped portion and the third encapsulation layer, and the fourth pattern portion may be disposed between the fourth stepped portion and the third encapsulation layer.

A display device according to embodiments of the disclosure may comprise a substrate including an emission area and a non-emission area, a buffer layer disposed on the substrate, a first planarization layer and a second planarization layer disposed on the buffer layer, a first encapsulation layer overlapping an upper surface and a side surface of each of the first planarization layer and the second planarization layer, a first protrusion formed at a portion where the upper surface and side surface of the first planarization layer contact, a second protrusion formed at a portion where the upper surface and side surface of the second planarization layer contact, a second encapsulation layer disposed on the first encapsulation layer, wherein at least a portion of the first encapsulation layer corresponds to the first protrusion and the second protrusion, and a third encapsulation layer disposed on the second encapsulation layer. The third encapsulation layer may contact the first encapsulation layer corresponding to the first protrusion and the second protrusion.

The above description has been presented to enable any person skilled in the art to make and use the technical idea of the disclosure, and has been provided in the context of a particular application and its requirements. Various modifications, additions and substitutions to the described embodiments will be readily apparent to those skilled in the art, and the general principles defined herein may be applied to other embodiments and applications without departing from the spirit and scope of the disclosure. The above description and the accompanying drawings provide an example of the technical idea of the disclosure for illustrative purposes only. That is, the disclosed embodiments are intended to illustrate the scope of the technical idea of the disclosure.

What is claimed:

1. A display device, comprising:
a substrate including an emission area and a non-emission area;
a buffer layer on the substrate;
a first planarization layer and a second planarization layer on the buffer layer;
a bank pattern on the second planarization layer in the non-emission area;
a first encapsulation layer overlapping an upper surface and a side surface of each of the bank pattern, the first planarization layer, and the second planarization layer;
a first protrusion located at a portion where the upper surface and side surface of the first planarization layer contact each other;
a second protrusion located at a portion where the upper surface and side surface of the second planarization layer contact each other;
a third protrusion located at a portion where the upper surface and side surface of the bank pattern contact each other;
a second encapsulation layer on the first encapsulation layer, wherein at least a portion of the first encapsulation layer corresponds to the first protrusion, the second protrusion, and the third protrusion; and
a third encapsulation layer on the second encapsulation layer,
wherein the third encapsulation layer contacts the first encapsulation layer corresponding to the first protrusion, the second protrusion, and the third protrusion.

2. The display device of claim 1, wherein an angle between the upper surface of the first planarization layer and the upper surface of the second planarization layer and the side surface of each of the first planarization layer and the second planarization layer is an obtuse angle.

3. The display device of claim 1, wherein an angle between the upper surface of the first planarization layer and the upper surface of the second planarization layer and the side surface of each of the first planarization layer and the second planarization layer is an acute angle.

4. The display device of claim 1, further comprising:
a first stepped portion located at a portion where an upper surface of the buffer layer and the side surface of the first planarization layer contact each other;
a second stepped portion located at a portion where the upper surface of the first planarization layer and the side surface of the second planarization layer contact each other; and
a third stepped portion located at a portion where the upper surface of the second planarization layer and the side surface of the bank pattern contact each other,
wherein at least a portion of the first encapsulation layer corresponds to the first stepped portion, the second stepped portion, and the third stepped portion.

5. The display device of claim 4, wherein the second encapsulation layer is between at least a portion of the first stepped portion, the second stepped portion, and the third stepped portion and the third encapsulation layer.

6. The display device of claim 4, wherein the second encapsulation layer includes a first pattern portion, a second pattern portion, and a third pattern portion, and
wherein the first pattern portion is between the first stepped portion and the third encapsulation layer, the second pattern portion is between the second stepped portion and the third encapsulation layer, and the third pattern portion is between the third stepped portion and the third encapsulation layer.

7. The display device of claim 1, further comprising:
a spacer on the bank pattern,
wherein a side surface of the spacer and the side surface of the bank pattern are non-overlapping with each other.

8. The display device of claim 7, further comprising:
a fourth protrusion located at a portion where an upper surface and a side surface of the spacer contact each other,
wherein at least a portion of the first encapsulation layer corresponds to the fourth protrusion and the third encapsulation layer contacts the first encapsulation layer corresponding to the fourth protrusion.

9. The display device of claim 7, further comprising:
a first stepped portion located at a portion where an upper surface of the buffer layer and the side surface of the first planarization layer contact each other;
a second stepped portion located at a portion where the upper surface of the first planarization layer and the side surface of the second planarization layer contact each other;
a third stepped portion located at a portion where the upper surface of the second planarization layer and the side surface of the bank pattern contact each other; and
a fourth stepped portion located at a portion where the upper surface of the bank pattern and the side surface of the spacer contact each other,
wherein at least a portion of the first encapsulation layer corresponds to the first stepped portion, the second stepped portion, the third stepped portion, and the fourth stepped portion.

10. The display device of claim 9, wherein the second encapsulation layer is between at least a portion of the first stepped portion, the second stepped portion, the third stepped portion, and the fourth stepped portion and the third encapsulation layer.

11. The display device of claim 9, wherein the second encapsulation layer includes a first pattern portion, a second pattern portion, a third pattern portion, and a fourth pattern portion, and
wherein the first pattern portion is between the first stepped portion and the third encapsulation layer, the second pattern portion is between the second stepped portion and the third encapsulation layer, the third pattern portion is disposed the third stepped portion and the third encapsulation layer, and the fourth pattern portion is between the fourth stepped portion and the third encapsulation layer.

12. A display device, comprising:
a substrate including an emission area and a non-emission area;
a buffer layer on the substrate;
a first planarization layer and a second planarization layer on the buffer layer;
a first encapsulation layer overlapping an upper surface and a side surface of each of the first planarization layer and the second planarization layer;
a first protrusion located at a portion where the upper surface and side surface of the first planarization layer contact each other;
a second protrusion located at a portion where the upper surface and side surface of the second planarization layer contact each other;
a second encapsulation layer on the first encapsulation layer, wherein at least a portion of the first encapsulation layer corresponds to the first protrusion and the second protrusion; and
a third encapsulation layer on the second encapsulation layer,
wherein the third encapsulation layer contacts the first encapsulation layer corresponding to the first protrusion and the second protrusion.
